(19) United States
(12) Patent Application Publication
(10) Pub. No.: US 2012/0081988 A1
(43) Pub. Date: Apr. 5, 2012

(54) SEMICONDUCTOR CIRCUIT AND SEMICONDUCTOR SYSTEM

(75) Inventors: Ki Ho KIM, Icheon-si (KR); Young Jun KU, Icheon-si (KR)

(73) Assignee: HYNIX SEMICONDUCTOR INC., Icheon-si (KR)

(21) Appl. No.: 12/983,158

(22) Filed: Dec. 31, 2010

(30) Foreign Application Priority Data
Sep. 30, 2010 (KR) 10-2010-0094948

(51) Int. Cl. G11C 8/08

(52) U.S. Cl. 365/230.06; 365/194

(57) ABSTRACT

A semiconductor circuit includes a data driving circuit configured to change a slew rate in response to a control signal and drive data at a changed slew rate, a core/peripheral circuit block configured to provide the data to the data driving circuit, and a channel/memory module information setting unit configured to set the control signal according to channel/memory module information.

### CROSS-REFERENCES TO RELATED APPLICATION

The present application claims priority under 35 U.S.C. §119(a) to Korean application number 10-2010-0094948, filed on, Sep. 30, 2010, in the Korean Intellectual Property Office, which is incorporated herein by reference in its entirety.

### BACKGROUND

1. Technical Field

The present invention relates to a semiconductor circuit, and more particularly, to a semiconductor circuit and a semiconductor system.

2. Related Art

A general semiconductor system has a configuration in which a memory controller is coupled to a plurality of memory modules, for example, dual in-line memory modules (DIMMs), through communication channels.

At this time, a memory system may be classified into a 1DPC (DIMM per Channel), a 2DPC, and a 3DPC according to the number of DIMMs coupled to each channel as illustrated in FIGS. 1A to 1C.

That is, the 1DPC represents a structure in which one DIMM is coupled to one channel, the 2DPC represents a structure in which two DIMMs are coupled to one channel, and the 3DPC represents a structure in which three DIMMs are coupled to one channel.

The DIMM includes a plurality of semiconductor memories, for example, dynamic random access memories (DRAMs), as illustrated in FIG. 2.

As illustrated in FIG. 3, a DRAM according to the conventional art includes a pre-driver block 10 and a main driver block 20 as data driving circuits for outputting data stored in an internal memory area (not shown) to outside the DRAM.

The pre-driver block 10 includes a plurality of pull-up pre-drivers PREDRV_UP and a plurality of pull-down pre-drivers PREDRV_DN.

The plurality of pull-up pre-drivers PREDRV_UP are selectively activated according to a drivability control signal ODTEN, and the activated pull-up pre-drivers PREDRV_UP generate pull-up signals UP<0:N-1> by driving data DATAR.

The plurality of pull-down pre-drivers PREDRV_DN are selectively activated according to the drivability control signal ODTEN, and the activated pull-down pre-drivers PREDRV_DN generate pull-down signals DN<0:N-1> by driving data DATAF.

The main driver block 20 includes a plurality of main drivers MDRV. The plurality of main drivers MDRV drive a data output terminal DQ in response to the pull-up signals UP<0:N-1> and the pull-down signals DN<0:N-1>.

The slew rate of the driving circuit of the semiconductor memory according to the conventional art as described above is determined by the pre-driver block 10 and the main driver block 20.

The slew rate of the pre-driver block 10 is a constant and the slew rate of the main driver block 20 is also a constant.

Accordingly, all DIMMs of the memory system according to the conventional art have a constant slew rate regardless of whether it's a 1DPC, a 2DPC, or a 3DPC.

The channel loading of the 2DPC is larger than that of the 1DPC and the channel loading of the 3DPC is larger than that of the 2DPC.

As described above, while all DIMMs have a constant slew rate regardless of the number of the DIMMs in each channel, the channel loading is increased as the number of the DIMMs in each channel is increased, causing a relative reduction in the slew rate. As a result, output characteristics are deteriorated.

When viewed from the data eyes illustrated in FIGS. 4A to 4C, it can be understood that the output characteristics are deteriorated as the number of the DIMMs in each channel is increased.

That is, in the case of the 2DPC, data eye loss occurs as compared with the 1DPC. In the case of the 3DPC, data eye loss is further increased.

### SUMMARY

A semiconductor circuit and a semiconductor system capable of substantially preventing the characteristics of an output signal from being deteriorated regardless of the number of memory modules in each channel are described herein.

In one embodiment of the present invention, a semiconductor circuit includes a data driving circuit configured to change a slew rate in response to a control signal and drive data at a changed slew rate, a core/peripheral circuit block configured to provide the data to the data driving circuit, and a channel/memory module information setting unit configured to set the control signal according to channel/memory module information.

In another embodiment of the present invention, a semiconductor system includes memory modules including one or more semiconductor memories configured to change a slew rate for data driving in response to information and drive data at a changed slew rate and a memory controller configured to provide the memory modules with the information defining a number of the memory modules coupled to each channel.

### BRIEF DESCRIPTION OF THE DRAWINGS

Features, aspects, and embodiments are described in conjunction with the attached drawings, in which:

FIGS. 1A to 1C are block diagrams illustrating the configuration of a general memory system;

FIG. 2 is a block diagram illustrating the configuration of the DIMM illustrated in FIG. 1;

FIG. 3 is a block diagram of a semiconductor memory according to the conventional art;

FIGS. 4A to 4C are graphs illustrating the data eye characteristics of a semiconductor memory according to the conventional art;

FIG. 5 is a block diagram of a memory system according to an embodiment of the present invention;

FIG. 6 is a block diagram illustrating the internal configuration of the data driving circuit illustrated in FIG. 5;

FIG. 7A is a waveform diagram illustrating an example of a slew rate adjustment method according to an embodiment of the present invention;

FIG. 7B is a circuit diagram illustrating a configuration example of a driving circuit based on FIG. 7A;

FIG. 8A is a waveform diagram illustrating another example of a slew rate adjustment method according to an embodiment of the present invention;

FIG. 8B is a circuit diagram illustrating a configuration example of a driving circuit based on FIG. 8A; and

FIGS. 9A to 9C are graphs illustrating the data eye characteristics of a semiconductor memory according to an embodiment of the present invention.

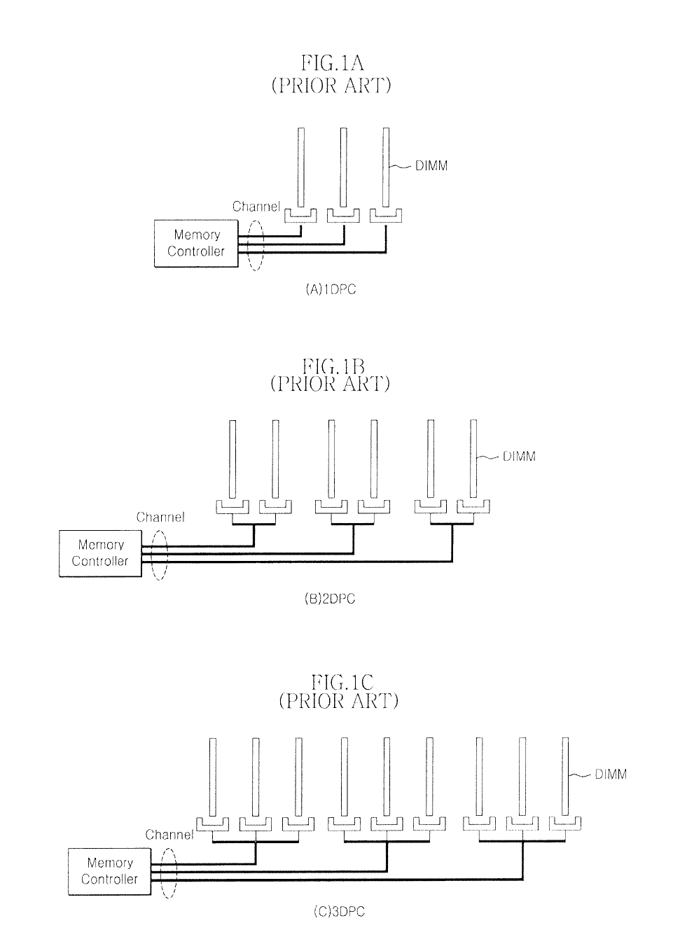

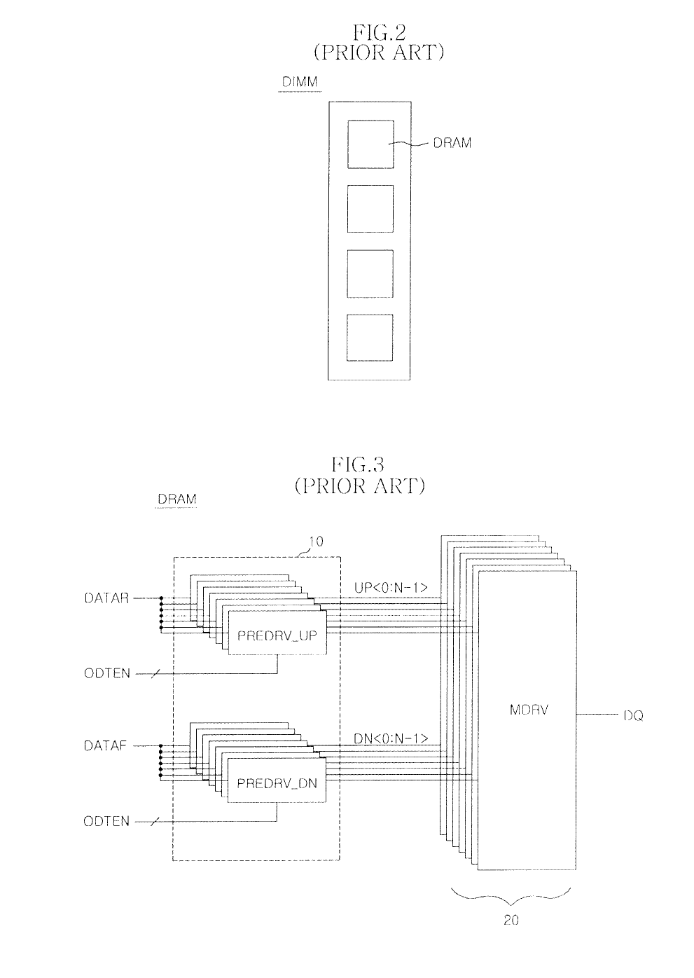

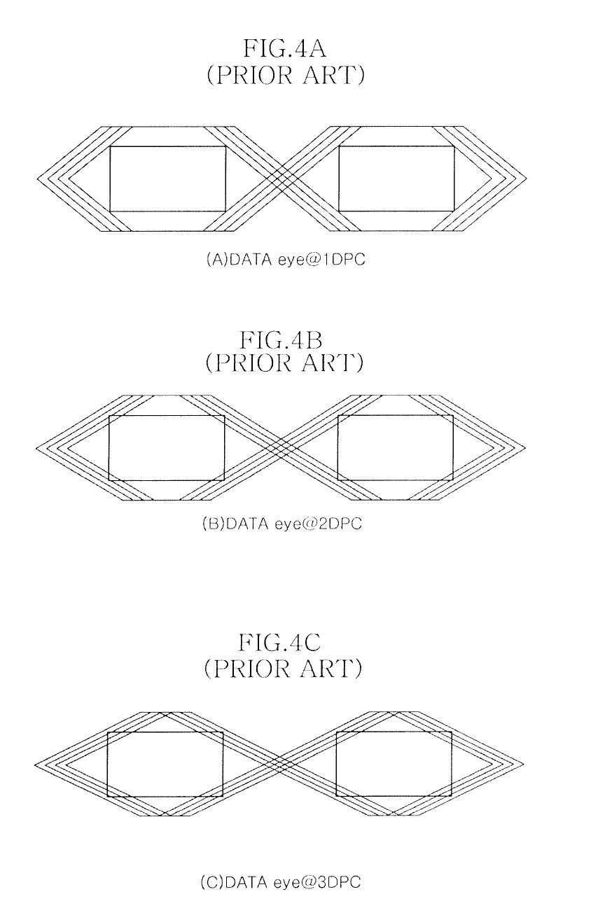

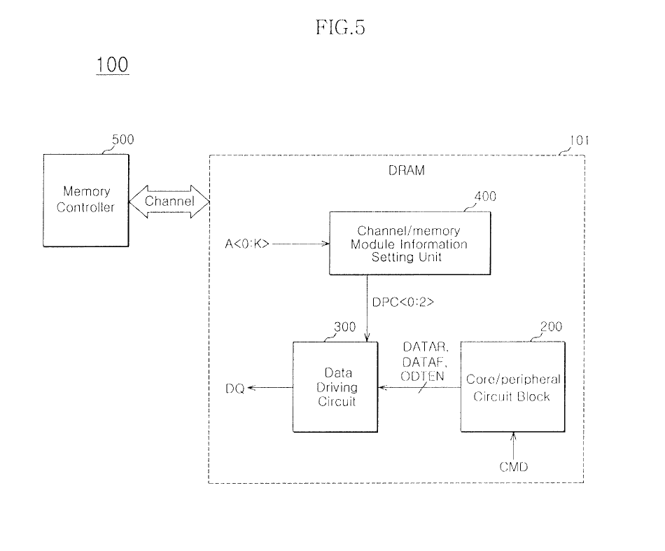

### DETAILED DESCRIPTION

Hereinafter, various embodiments of a semiconductor circuit and a semiconductor system according to the present invention will be described in detail with reference to the accompanying drawings.

Referring to FIG. 5, there is shown a block diagram of a semiconductor system according to an embodiment of the invention, that is, a memory system 100 that includes a semiconductor memory 101 (DRAM) and a memory controller 500.

FIG. 5 illustrates the semiconductor memory 101, which may be one of many memory modules coupled to the memory controller 500.

The memory controller 500 is configured to provide channel/memory module information to the semiconductor memory 101. The channel/memory module information is information regarding the number of memory modules coupled to each channel.

The memory controller 500 may allow the channel/memory module information to be included in some signal bits of address signals A<0:K> and, thereby, provide the channel/memory module information to the semiconductor memory 101.

The semiconductor memory 101 is configured to change a slew rate for data driving in response to the channel/memory module information and drive data at the changed slew rate.

The semiconductor memory 101 includes a core/peripheral circuit block 200, a data driving circuit 300, and a channel/memory module information setting unit 400.

The core/peripheral circuit block 200 includes a memory area and a circuit configuration for controlling data input/output to and from the memory area.

The core/peripheral circuit block 200 is configured to provide the data driving circuit 300 with the data DATAR and DATAF and a drivability control signal ODTEN in response to a command CMD.

The data driving circuit 300 is configured to change a slew rate in response to control signals DPC<0:2> and drive the data DATAR and DATAF at the changed slew rate.

The drivability of the data driving circuit 300 is changed according to the drivability control signal ODTEN.

The channel/memory module information setting unit 400 is configured to set the control signals DPC<0:2> in response to the address signals A<0:K>.

The channel/memory module information setting unit 400 may include a mode register set (MRS).

The mode register set is for setting the operation modes of the semiconductor memory 101 and may set various operation modes according to address signals.

On the basis of a DDR3, among the address signals A<0:K> inputted to the mode register set, some signal bits, for example, A0 and A1, are assigned for setting the operation modes, and the other signal bits are residue signal bits.

In this regard, according to an embodiment of the invention, the channel/memory module information is included in the residue signal bits of the address signals A<0:K> used for the mode register set and is transmitted.

Meanwhile, the channel/memory module information setting unit 400 may also have a different form, for example, a fuse set, other than the mode register set. In such a case, the channel/memory module information may not be received from the memory controller 500, but may be independently set.

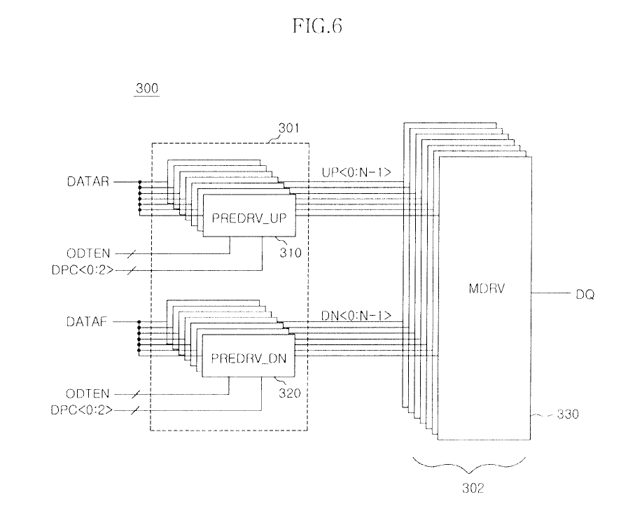

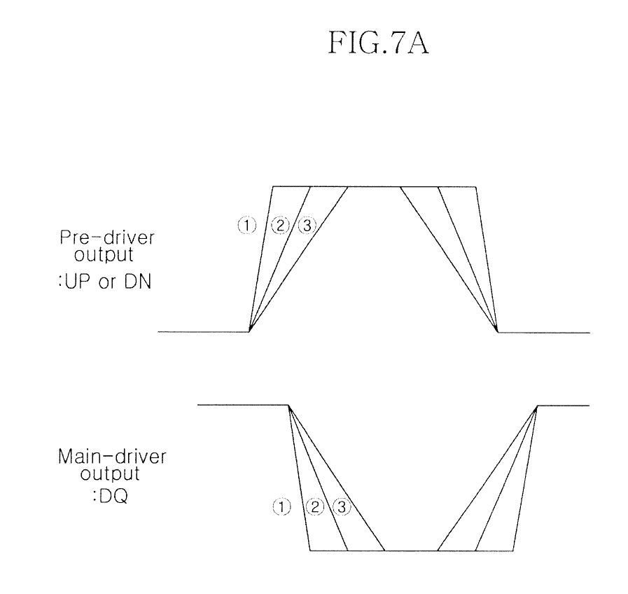

Referring to FIG. 6, the data driving circuit 300 includes a pre-driver block 301 and a main driver block 302.

The pre-driver block 301 includes a plurality of pull-up pre-drivers PREDRV_UP and a plurality of pull-down pre-drivers PREDRV_DN.

The plurality of pull-up pre-drivers PREDRV_UP are configured to receive the data DATAR, the drivability control signal ODTEN, and the control signals DPC<0:2>.

The plurality of pull-up pre-drivers PREDRV_UP are configured to be selectively activated according to the drivability control signal ODTEN, and the activated pull-up pre-drivers PREDRV_UP are configured to generate pull-up signals UP<0:N-1> by driving the data DATAR.

The plurality of pull-down pre-drivers PREDRV_DN are configured to receive the data DATAF, the drivability control signal ODTEN, and the control signals DPC<0:2>.

The plurality of pull-down pre-drivers PREDRV_DN are configured to be selectively activated according to the drivability control signal ODTEN, and the activated pull-down pre-drivers PREDRV_DN are configured to generate pull-down signals DN<0:N-1> by driving the data DATAF.

The main driver block 302 includes a plurality of main drivers MDRV. The plurality of main drivers MDRV are configured to drive a data output terminal DQ in response to the pull-up signals UP<0:N-1> and the pull-down signals DN<0:N-1>.

According to the embodiment of the invention as described above, the slew rate of the data driving circuit 300 may be changed according to two methods.

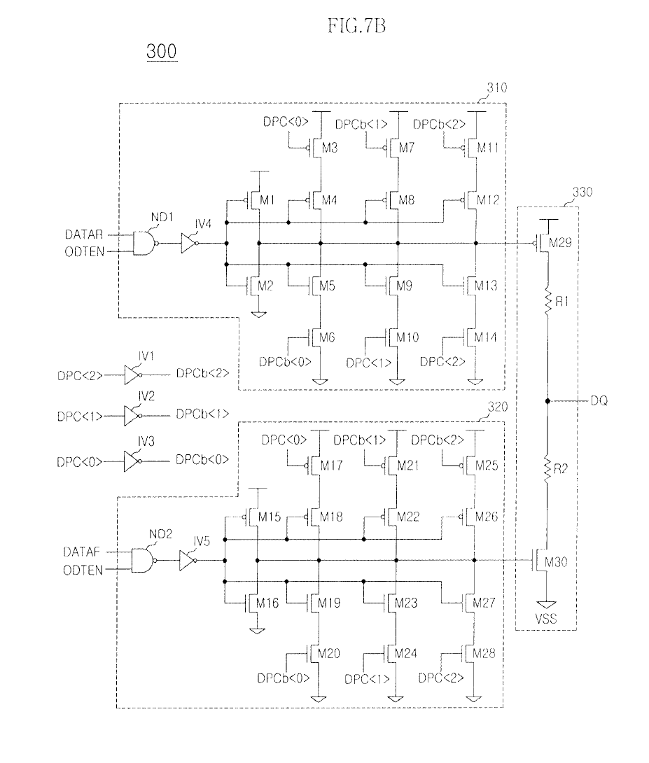

According to the first method, as illustrated in FIG. 7A, the slew rate of the final output (that is, the data output terminal DQ) of the main driver block 302 is changed by changing the slew rate of the pre-driver block 301 using the control signals DPC<0:2>.

That is, the slew rates of all pre-drivers of the pre-driver block 301 are increased in sequence for 1DPC, 2DPC, and 3DPC.

An embodiment of the data driving circuit 300 configured according to the method of FIG. 7A is illustrated in FIG. 7B. FIG. 7B illustrates only one pull-up pre-driver PREDRV_UP, one pull-down pre-driver PREDRV_DN, and one main driver MDRV.

As illustrated in FIG. 7B, the data driving circuit 300 includes a pull-up pre-driver 310, a pull-down pre-driver 320, a main driver 330, and a plurality of inverters IV1 to IV3 for generating signals DPCb<0:1> obtained by inverting the control signals DPC<0:2>.

The pull-up pre-driver 310 includes a NAND gate ND1, an inverter IV4, and a plurality of driver legs M1 and M2, M3 to M6, M7 to M10, and M11 to M14, where the labels M1 and M2, M3 to M6, M7 to M10, and M11 to M14 indicate transistors for the respective driver legs.

Similarly, the pull-down pre-driver 320 includes a NAND gate ND2, an inverter IV5, and a plurality of driver legs M15 and M16, M17 to M20, M21 to M24 and M25 to M28, where the labels M15 and M16, M17 to M20, M21 to M24, and M25 to M28 indicate transistors for the respective driver legs.

The main driver 330 includes the transistors M29 and M30, and the resistors R1 and R2.

At this time, the control signals DPC<0:2> may be configured as Table 1 below.

TABLE 1

| | 1 DPC | Default | 2 DPC | 3 DPC |
|---|---|---|---|---|
| DPC<0> | 1 | 0 | 0 | 0 |
| DPC<1> | 0 | 0 | 1 | 1 |
| DPC<2> | 0 | 0 | 0 | 1 |

The operation of the data driving circuit 300 illustrated in FIG. 7B will be described with reference to Table 1 below.

When no channel/memory module information exists, that is, in a default state, the control signals DPC<0:2> have a value of “000”, and two driver legs M1 and M2 and M3 to M6 of the pull-up pre-driver 310 and two driver legs M15 and M16 and M17 to M20 of the pull-down pre-driver 320 are activated. The default state is set such that the slew rate of the pre-driver block 301 (FIG. 6) has a value corresponding to the middle of 1DPC and 2DPC values, thereby allowing the data driving circuit 300 to have a slew rate corresponding to the middle of 1DPC and 2DPC rates.

When the channel/memory module information selects 1DPC, it is necessary to reduce the slew rate as compared with the default state. At this time, the control signals DPC<0:2> have a value of “100”, and the number of driver legs to be activated is reduced as compared with the default state. That is, one driver leg M1 and M2 of the pull-up pre-driver 310 and one driver leg M15 and M16 of the pull-down pre-driver 320 are activated.

When the channel/memory module information selects 2DPC, it is necessary to increase the slew rate as compared with the default state. At this time, the control signals DPC<0:2> have a value of “010”, and the number of driver legs to be activated is increased as compared with the default state. That is, three driver legs M1 and M2, M3 to M6, and M7 to M10 of the pull-up pre-driver 310 and three driver legs M15 and M16, M17 to M20, and M21 to M24 of the pull-down pre-driver 320 are activated.

When the channel/memory module information selects 3DPC, it is necessary to increase the slew rate as compared with 2DPC. At this time, the control signals DPC<0:2> have a value of “011”, and the number of driver legs to be activated is increased as compared with 2DPC. That is, all driver legs M1 and M2, M3 to M6, M7 to M10, and M11 to M14 of the pull-up pre-driver 310 and all driver legs M15 and M16, M17 to M20, M21 to M24, and M25 to M28 of the pull-down pre-driver 320 are activated.

When the drivability control signal ODTEN is asserted, the pull-up pre-driver 310 and the pull-down pre-driver 320 drive the data DATAR and DATAF at the slew rates as described above, and thus the main driver 330 drives the data output terminal DQ.

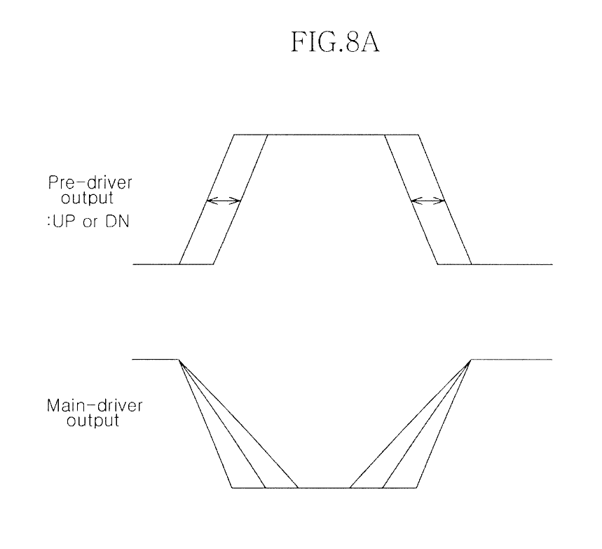

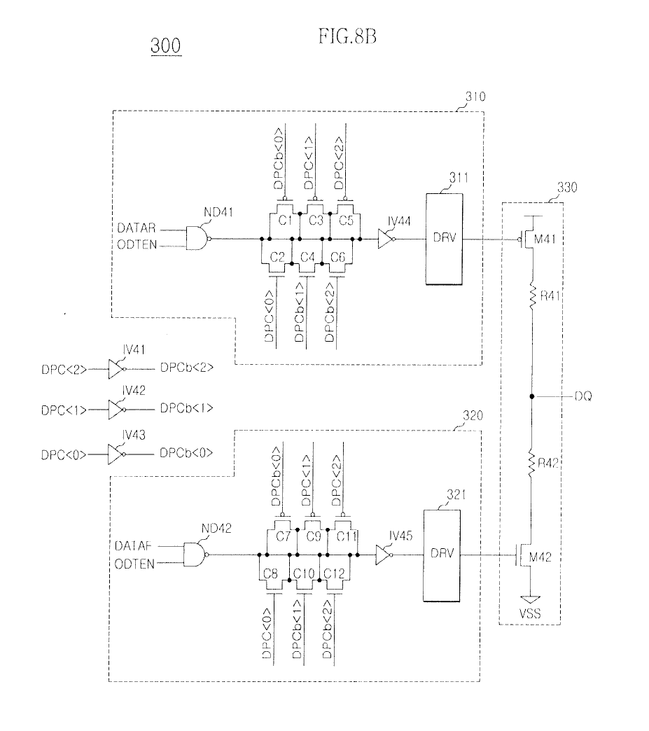

According to the second method, as illustrated in FIG. 8A, the slew rate of the final output (that is, the data output terminal DQ) of the main driver block 302 is changed by changing the activation timing delay time of the pre-driver block 301 using the control signals DPC<0:2>.

An embodiment of the data driving circuit 300 configured according to the method of FIG. 8A is illustrated in FIG. 8B. FIG. 8B illustrates only one pull-up pre-driver PREDRV_UP, one pull-down pre-driver PREDRV_DN and one main driver MDRV.

As illustrated in FIG. 8B, the data driving circuit 300 includes a pull-up pre-driver 310, a pull-down pre-driver 320, a main driver 330, and a plurality of inverters IV41 to IV43 for generating signals DPCb<0:1> obtained by inverting the control signals DPC<0:2>.

The pull-up pre-driver 310 includes a NAND gate ND41, an inverter IV44, a plurality of delay legs C1 and C2, C3 and C4, and C5 and C6, and a driver 311, where the labels C1 and C2, C3 and C4, and C5 and C6 indicate capacitors for the respective driver legs.

The pull-down pre-driver 320 includes a NAND gate ND42, an inverter IV45, a plurality of delay legs C7 and C8, C9 and C10, and C11 and C12, and a driver 321, where the labels C7 and C8, C9 and C10 and C11 and C12 indicate capacitors for the respective driver legs.

The main driver 330 includes transistors M41 and M42 and resistors R41 and R42.

The operation of the data driving circuit 300 illustrated in FIG. 8B will be described with reference to Table 1 above.

When no channel/memory module information exists, that is, in a default state, the control signals DPC<0:2> have a value of “000”, and two delay legs C3 and C4 and C5 and C6 of the pull-up pre-driver 310 and two delay legs C9 and C10 and C11 and C12 of the pull-down pre-driver 320 are activated. The default state is set such that the activation timing delay time of the pre-driver block 301 has a value corresponding to the middle of the values for 1DPC and 2DPC, thereby allowing the data driving circuit 300 to have a slew rate corresponding to the middle of the 1DPC and 2DPC rates.

When the channel/memory module information selects 1DPC, it is necessary to reduce the slew rate as compared with the default state. To this end, the activation timing delay time of the pre-driver block 301 is increased as compared with the default state. At this time, the control signals DPC<0:2> have a value of “100”, and the number of delay legs to be activated is increased as compared with the default state. That is, all delay legs C1 and C2, C3 and C4, and C5 and C6 of the pull-up pre-driver 310 and all delay legs C7 and C8, C9 and C10, and C11 and C12 of the pull-down pre-driver 320 are activated.

When the channel/memory module information selects 2DPC, it is necessary to increase the slew rate as compared with the default state. To this end, the activation timing delay time of the pre-driver block 301 is reduced as compared with the default state. At this time, the control signals DPC<0:2>have a value of “010”, and the number of driver legs to be activated is reduced as compared with the default state. That is, one delay leg C5 and C6 of the pull-up pre-driver 310 and one delay leg C11 and C12 of the pull-down pre-driver 320 are activated.

When the channel/memory module information selects 3DPC, it is necessary to increase the slew rate as compared with 2DPC. To this end, the activation timing delay time of the pre-driver block 301 is reduced as compared with 2DPC. At this time, since the control signals DPC<0:2> have a value of “011”, no delay legs are activated. That is, all delay legs C1 and C2, C3 and C4, and C5 and C6 of the pull-up pre-driver 310 and all delay legs C7 and C8, C9 and C10, and C11 and C12 of the pull-down pre-driver 320 are deactivated.

When the drivability control signal ODTEN is activated, the pull-up pre-driver 310 and the pull-down pre-driver 320 drive the data DATAR and DATAF at the slew rates as described above, and thus the main driver 330 drives the data output terminal DQ.

As described above, according to various embodiments of the invention, the slew rate is changed to have an optimal value according to the number of memory modules in each channel, so that the characteristics of an output signal are substantially prevented from being deteriorated.

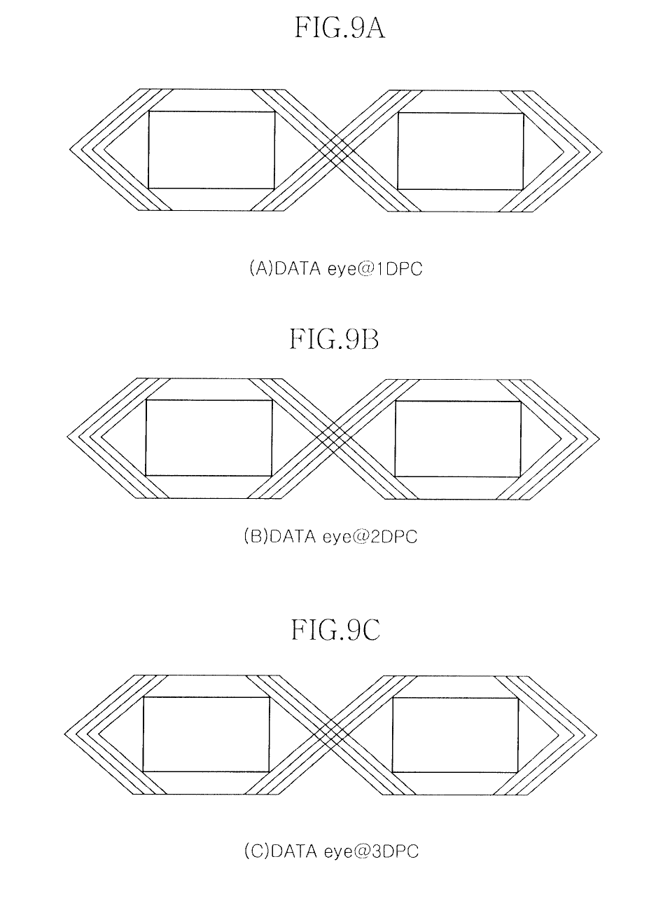

That is, when viewed from the data eyes illustrated in FIGS. 9A to 9C, it can be understood that the characteristics of an output signal are constantly maintained regardless of the number of the DIMMs in each channel.

According to various embodiments of the invention, the slew rate of a memory module is compensated according to the number of memory modules in each channel, so that output characteristics are substantially prevented from being deteriorated.

While certain embodiments have been described above, it will be understood to those skilled in the art that the embodiments described are by way of example only. Accordingly, the semiconductor circuit and the semiconductor system described herein should not be limited based on the described embodiments. Rather, the semiconductor circuit and the semiconductor system described herein should only be limited in light of the claims that follow when taken in conjunction with the above description and accompanying drawings.

What is claimed is:

1. A semiconductor circuit in a semiconductor memory comprising:
a data driving circuit configured to change a slew rate in response to a control signal and drive data at a changed slew rate;
a core/peripheral circuit block configured to provide the data to the data driving circuit; and
a channel/memory module information setting unit configured to set the control signal according to channel/memory module information.

2. The semiconductor circuit according to claim 1, wherein the channel/memory module information setting unit is configured to receive the channel/memory module information from outside of the semiconductor memory.

3. The semiconductor circuit according to claim 1, wherein the channel/memory module information setting unit is configured to receive the channel/memory module information from an address input unit.

4. The semiconductor circuit according to claim 1, wherein the data driving circuit comprises:
a pre-driver block configured to receive the control signal and the data; and
a main driver block configured to drive a data output terminal according to output of the pre-driver block.

5. The semiconductor circuit according to claim 4, wherein the data driving circuit is configured to change a slew rate of the pre-driver block in response to the control signal.

6. The semiconductor circuit according to claim 4, wherein the pre-driver block includes a plurality of driver legs and is configured to selectively activate each of a number of driver legs in response to the control signal.

7. The semiconductor circuit according to claim 4, wherein the data driving circuit is configured to change an activation timing delay time of the pre-driver block in response to the control signal.

8. The semiconductor circuit according to claim 4, wherein the pre-driver block comprises:
a driver; and
a plurality of delay legs coupled to a data input path of the driver,
wherein a number of driver legs to be activated is changed in response to the control signal.

9. The semiconductor circuit according to claim 1, wherein the core/peripheral circuit block is configured to provide a drivability control signal to the data driving circuit.

10. The semiconductor circuit according to claim 9, wherein data drivability of the data driving circuit is changed according to the drivability control signal.

11. A semiconductor system comprising:
memory modules including one or more semiconductor memories configured to change a slew rate for data driving in response to information; and
a memory controller configured to provide the memory modules with the information defining a number of the memory modules coupled to each channel.

12. The semiconductor system according to claim 11, wherein the memory controller is configured to provide the semiconductor memory with the information through an address channel.

13. The semiconductor system according to claim 11, wherein the semiconductor memory comprises:
a data driving circuit configured to change a slew rate in response to a control signal;
a core/peripheral circuit block configured to provide data to the data driving circuit; and
a mode register set configured to set the control signal according to the information.

14. The semiconductor system according to claim 13, wherein the data driving circuit comprises:
a pre-driver block; and
a main driver block configured to drive a data output terminal according to output of the pre-driver block,
wherein the data driving circuit is configured to change a slew rate of the pre-driver block in response to the control signal.

15. The semiconductor system according to claim 14, wherein the pre-driver block includes a plurality of driver legs and is configured to change a number of driver legs to be activated in response to the control signal.

16. The semiconductor system according to claim 13, wherein the data driving circuit comprises:
a pre-driver block; and
a main driver block configured to drive a data output terminal according to output of the pre-driver block,
wherein the data driving circuit is configured to change an activation timing delay time of the pre-driver block in response to the control signal.

17. The semiconductor system according to claim 16, wherein the pre-driver block comprises:
a driver; and
a plurality of delay legs coupled to a data input path of the driver,
wherein a number of driver legs to be activated is changed in response to the control signal.
